(19) United States
(12) Patent Application Publication
(10) Pub. No.: US 2025/0125291 A1
(43) Pub. Date: Apr. 17, 2025

(54) SEMICONDUCTOR PRODUCT AND METHOD FOR MANUFACTURING A SEMICONDUCTOR PRODUCT

(71) Applicants: MICLEDI MICRODISPLAYS BV, Leuven (BE); IMEC VZW, Leuven (BE)

(72) Inventors: Emmanuel LE BOULBAR, Wezembeek-Oppem (BE); Soeren STEUDEL, Herent (BE); Johan VERTOMMEN, Holsbeek (BE); Robert MILLER, Leuven (BE); Joeri DE VOS, Leuven (BE); Stefaan VAN HUYLENBROECK, Leuven (BE); Eric BEYNE, Leuven (BE); Liesbeth WITTERS, Leuven (BE)

(21) Appl. No.: 18/685,402

(22) PCT Filed: Feb. 21, 2023
(86) PCT No.: PCT/EP2023/054259

§ 371 Date: Feb. 21, 2024

(30) Foreign Application Priority Data
Mar. 24, 2022 (EP) 22164115.2
Feb. 7, 2023 (EP) 23155260.5

(51) Int. Cl. H01L 23/00

(52) U.S. Cl. CPC H01L 24/05; H01L 24/08; H01L 24/80; H01L 2224/05647; H01L 2224/05657; H01L 2224/05684; H01L 2224/08145; H01L 2224/80895; H01L 2924/37001

(57) ABSTRACT

A semiconductor product is provided. The semiconductor product comprises a first wafer (21) comprising a first active pad array (21a), and at least a second wafer (22) comprising at least a second active pad array (22a). In this context, the first wafer (21) and the at least one second wafer (22) are bonded together. In addition to this, the first wafer (21) and/or the at least one second wafer (22) comprises a transition area (23) being directly adjacent to the first active pad array (21a) and/or the at least one second active pad array (22a).

The invention relates to a semiconductor product, especially comprising at least two wafers being bond together, and a method for manufacturing a semiconductor product.

Generally, in times of an increasing number of complex circuitries, there is a growing need of a semiconductor product and a method for manufacturing a semiconductor product which allows for implementing such circuitries.

US 2020/0091115 A1 relates to a structure including a first dielectric layer overlying a first substrate. A first connection pad is disposed in a top surface of the first dielectric layer and contacts a first redistribution line. A first dummy pad is disposed in the top surface of the first dielectric layer. The first dummy pad contacts the first redistribution line. A second dielectric layer overlies a second substrate. A second connection pad and a second dummy pad are disposed in the top surface of the second dielectric layer. The second connection pad is bonded to the first connection pad. The first dummy pad is positioned in a manner that it is offset from the second dummy pad so that the first dummy pad and the second dummy pad do not have contact with each other. Disadvantageously, such a configuration does not prevent sharp transitions with respect to the dielectric height profiles of the respective wafers, which exemplarily leads to voids between the wafers, and thus also to a defective bonding.

Accordingly, there is the object to provide a semiconductor product and a method for manufacturing a semiconductor product, wherein the semiconductor product especially comprises at least two wafer being bond together, in order to allow for preventing voids between the at least two wafers, thereby ensuring a high accuracy and efficiency of the respective bonding.

This object is solved by the features of the first independent claim for a semiconductor product and the features of the second independent claim for a method for manufacturing a semiconductor product. The dependent claims contain further developments.

According to a first aspect of the invention, a semiconductor product is provided. Said semiconductor product comprises a first wafer comprising a first active pad array, and at least a second wafer comprising at least a second active pad array. In this context, the first wafer and the at least one second wafer are bonded together. In addition to this, the first wafer and/or the at least one second wafer comprises a transition area being directly adjacent to the first active pad array and/or the at least one second active pad array. Advantageously, voids between the at least two wafers can be avoided, which leads to a highly accurate and efficient bonding.

With respect to the above-mentioned transition area, it is noted that the corresponding transition can be made in a smooth manner. Accordingly, the transition area can also be seen as a transition smoothing area.

According to a first preferred implementation form of the first aspect of the invention, the first wafer and the at least one second wafer are bonded together according to a hybrid bonding technique. Advantageously, for instance, a flexible usage can be guaranteed, which further increases efficiency.

According to a second preferred implementation form of the first aspect of the invention, the transition area comprises an inactive pad array. Advantageously, for example, the transition area can be designed in a simple manner, thereby ensuring a particularly high efficiency.

With respect to said inactive pad array, it is noted such an array can also be referred to as dummy pad array in the following. Analogously, the term “inactive” can be referred to as “dummy”, and vice versa. It is further noted that said term “inactive” may especially be understood as “electrically inactive”.

According to a further preferred implementation form of the first aspect of the invention, the first active pad array comprises a first ratio of an electrically conducting material over the corresponding area of the first active pad array. In addition to this or as an alternative, the at least one second active pad array comprises at least a second ratio of an electrically conducting material over the corresponding area of the at least one second active pad array. Further additionally or further alternatively, the electrically conducting material comprises or is copper and/or cobalt and/or tungsten. Advantageously, for instance, the first ratio and the at least one second ratio may be different, thereby preventing voids and defective bonding in an accurate and efficient manner.

With respect to said electrically conducting material, it is noted that the electrically conducting material can especially comprise or be an alloy comprising at least one of copper, cobalt, tungsten, or any combination thereof.

With respect to the first ratio and the at least one second ratio, it is noted that said ratios can especially be at least similar with respect to each other or even the same.

According to a further preferred implementation form of the first aspect of the invention, the first ratio or the at least one second ratio of the electrically conducting material is between 1% and 12%, preferably between 1% and 7%, more preferably between 2% and 4%, most preferably 3%. In addition to this or as an alternative, the at least one second ratio or the first ratio of the electrically conducting material is between 1% and 27%, preferably between 1% and 19%, more preferably between 11% and 13%, most preferably 12%. Advantageously, for example, in this manner, preventing voids and defective bonding can further be optimized.

According to a further preferred implementation form of the first aspect of the invention, the transition area comprises a third ratio of an electrically conducting material, especially comprising or being copper and/or cobalt and/or tungsten, over the corresponding area of the transition area. Advantageously, for instance, the third ratio can easily be adjusted by changing the size and/or the shape of the pads of the inactive pad array.

With respect to said electrically conducting material, it is noted that the electrically conducting material can especially comprise or be an alloy comprising at least one of copper, cobalt, tungsten, or any combination thereof.

According to a further preferred implementation form of the first aspect of the invention, the third ratio of the electrically conducting material does deviate not more than 400%, preferably not more than 270%, more preferably not more than 225%, most preferably not more than 56.25%, from the at least one second ratio of the electrically conducting material over the corresponding area of the at least one second active pad array. Advantageously, for example, in this manner, preventing voids and defective bonding can further be optimized.

According to a further preferred implementation form of the first aspect of the invention, the third ratio of the electrically conducting material does deviate not more than 400%, preferably not more than 270%, more preferably not more than 225%, most preferably not more than 56.25%, from the first ratio of the electrically conducting material over the corresponding area of the first active pad array. Advantageously, for instance, with the aid of this configuration, preventing voids and defective bonding can further be improved.

According to a further preferred implementation form of the first aspect of the invention, the first wafer comprises a first further area comprising a first further ratio of an electrically conducting material over the corresponding area of the first further area. In addition to this or as an alternative, the at least one second wafer comprises at least a second further area comprising at least a second further ratio of an electrically conducting material over the corresponding area of the at least one second further area. Further additionally or further alternatively, the electrically conducting material comprises or is copper and/or cobalt and/or tungsten. Advantageously, for example, the respective slope direction can easily be engineered, which allows for enabling the corresponding wafer surfaces to follow each other.

With respect to said electrically conducting material, it is noted that the electrically conducting material can especially comprise or be an alloy comprising at least one of copper, cobalt, tungsten, or any combination thereof.

According to a further preferred implementation form of the first aspect of the invention, the first further area is directly adjacent to the transition area and/or not directly adjacent to the first active pad array. In addition to this or as an alternative the at least one second further area is directly adjacent to the transition area and/or not directly adjacent to the at least one second active pad array. Advantageously, for instance, by enabling the corresponding wafer surfaces to follow each other, voids between the wafers can accurately and efficiently be avoided.

According to a further preferred implementation form of the first aspect of the invention, the first further area comprises a first further inactive pad array. In addition to this or as an alternative, the at least one second further area comprises at least a second further inactive pad array. Advantageously, for example, both the first further area and the at least one second further area can easily, and thus also efficiently, be designed.

According to a further preferred implementation form of the first aspect of the invention, the first further ratio of the electrically conducting material does deviate not more than 56.25%, preferably not more than 25%, more preferably not more than 12.5%, most preferably not more than 1%, from the at least one second ratio of the electrically conducting material over the corresponding area of the at least one second active pad array. In addition to this or as an alternative, the at least one second further ratio of the electrically conducting material does deviate not more than 56.25%, preferably not more than 25%, more preferably not more than 12.5%, most preferably not more than 1%, from the first ratio of the electrically conducting material over the corresponding area of the first active pad array. Advantageously, for instance, with the aid of this configuration, preventing voids and defective bonding can further be improved.

According to a further preferred implementation form of the first aspect of the invention, the first further ratio of the electrically conducting material over the corresponding area of the first further area changes according to a first gradient. In addition to this or as an alternative, the at least one second further ratio of the electrically conducting material over the corresponding area of the at least one second further area changes according to a second gradient. Advantageously, for example, both the first gradient and the second gradient can easily be achieved exemplarily by changing the pattern arrangement with respect to the first further inactive pad array or the at least one second further inactive pad array, respectively.

According to a further preferred implementation form of the first aspect of the invention, the third ratio of the electrically conducting material over the corresponding area of the transition area changes according to a third gradient. Advantageously, for instance, the third gradient can easily be achieved exemplarily by changing the corresponding element shape with respect to the inactive pad array. Further advantageously, the gradient can be modified with respect to the respective ratio of the corresponding active array. In this context, for instance, the corresponding element and/or repetitive structure and/or the corresponding shape of the respective pads can be modified.

Before the second aspect of the invention and its preferred implementation forms are explained in the following, it is noted that all the benefits mentioned above regarding the first aspect of the invention and its preferred implementation forms do analogously apply.

According to a second aspect of the invention, a method for manufacturing a semiconductor product is provided. Said method comprises the steps of providing a first wafer comprising a first active pad array, providing at least a second wafer comprising at least a second active pad array, and bonding the first wafer and the at least one second wafer together. In this context, the first wafer and/or the at least one second wafer comprises a transition area being directly adjacent to the first active pad array and/or the at least one second active pad array.

With respect to the above-mentioned transition area, it is noted that the corresponding transition can be made in a smooth manner. Accordingly, the transition area can also be seen as a transition smoothing area.

According to a first preferred implementation form of the second aspect of the invention, the first wafer and the at least one second wafer are bonded together according to a hybrid bonding technique.

According to a second preferred implementation form of the second aspect of the invention, the transition area comprises an inactive pad array.

According to a further preferred implementation form of the second aspect of the invention, the first active pad array comprises a first ratio of an electrically conducting material over the corresponding area of the first active pad array. In addition to this or as an alternative, the at least one second active pad array comprises at least a second ratio of an electrically conducting material over the corresponding area of the at least one second active pad array. Further additionally or further alternatively, the electrically conducting material comprises or is copper and/or cobalt and/or tungsten.

With respect to said electrically conducting material, it is noted that the electrically conducting material can especially comprise or be an alloy comprising at least one of copper, cobalt, tungsten, or any combination thereof.

With respect to the first ratio and the at least one second ratio, it is noted that said ratios can especially be at least similar with respect to each other or even the same.

According to a further preferred implementation form of the second aspect of the invention, the first ratio or the at least one second ratio of the electrically conducting material is between 1% and 12%, preferably between 1% and 7%, more preferably between 2% and 4%, most preferably 3%. In addition to this or as an alternative, the at least one second ratio or the first ratio of the electrically conducting material is between 1% and 27%, preferably between 1% and 19%, more preferably between 11% and 13%, most preferably 12%.

According to a further preferred implementation form of the second aspect of the invention, the transition area comprises a third ratio of an electrically conducting material, especially comprising or being copper and/or cobalt and/or tungsten, over the corresponding area of the transition area.

With respect to said electrically conducting material, it is noted that the electrically conducting material can especially comprise or be an alloy comprising at least one of copper, cobalt, tungsten, or any combination thereof.

According to a further preferred implementation form of the second aspect of the invention, the third ratio of the electrically conducting material does deviate not more than 400%, preferably not more than 270%, more preferably not more than 225%, most preferably not more than 56.25%, from the at least one second ratio of the electrically conducting material over the corresponding area of the at least one second active pad array.

According to a further preferred implementation form of the second aspect of the invention, the third ratio of the electrically conducting material does deviate not more than 400%, preferably not more than 270%, more preferably not more than 225%, most preferably not more than 56.25%, from the first ratio of the electrically conducting material over the corresponding area of the first active pad array.

According to a further preferred implementation form of the second aspect of the invention, the first wafer comprises a first further area comprising a first further ratio of an electrically conducting material over the corresponding area of the first further area. In addition to this or as an alternative, the at least one second wafer comprises at least a second further area comprising at least a second further ratio of an electrically conducting material over the corresponding area of the at least one second further area. Further additionally or further alternatively, the electrically conducting material comprises or is copper and/or cobalt and/or tungsten.

With respect to said electrically conducting material, it is noted that the electrically conducting material can especially comprise or be an alloy comprising at least one of copper, cobalt, tungsten, or any combination thereof.

According to a further preferred implementation form of the second aspect of the invention, the first further area is directly adjacent to the transition area and/or not directly adjacent to the first active pad array. In addition to this or as an alternative the at least one second further area is directly adjacent to the transition area and/or not directly adjacent to the at least one second active pad array.

According to a further preferred implementation form of the second aspect of the invention, the first further area comprises a first further inactive pad array. In addition to this or as an alternative, the at least one second further area comprises at least a second further inactive pad array.

According to a further preferred implementation form of the second aspect of the invention, the first further ratio of the electrically conducting material does deviate not more than 56.25%, preferably not more than 25%, more preferably not more than 12.5%, most preferably not more than 1%, from the at least one second ratio of the electrically conducting material over the corresponding area of the at least one second active pad array. In addition to this or as an alternative, the at least one second further ratio of the electrically conducting material does deviate not more than 56.25%, preferably not more than 25%, more preferably not more than 12.5%, most preferably not more than 1%, from the first ratio of the electrically conducting material over the corresponding area of the first active pad array.

According to a further preferred implementation form of the second aspect of the invention, the first further ratio of the electrically conducting material over the corresponding area of the first further area changes according to a first gradient. In addition to this or as an alternative, the at least one second further ratio of the electrically conducting material over the corresponding area of the at least one second further area changes according to a second gradient.

According to a further preferred implementation form of the second aspect of the invention, the third ratio of the electrically conducting material over the corresponding area of the transition area changes according to a third gradient.

Exemplary embodiments of the invention are now further explained with respect to the drawings by way of example only, and not for limitation. In the drawings:

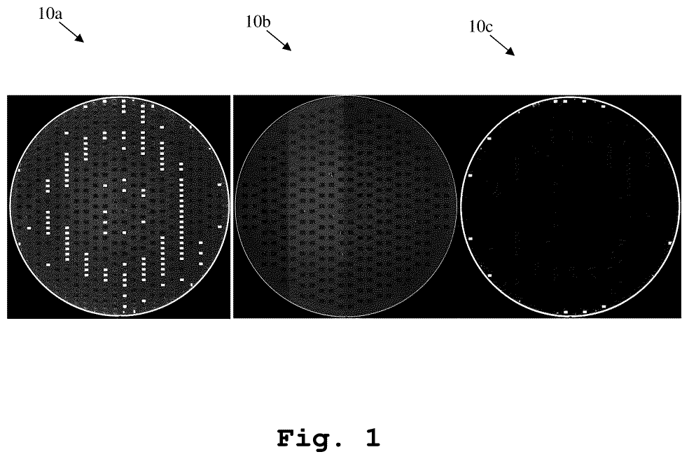

FIG. 1 shows exemplary surface acoustic wave images which highlight images obtained for (left) wafer bonded with array on top and bottom, (center) top wafer bonded to blanket carrier wafer, and (right) bottom wafer bonded to blanket carrier;

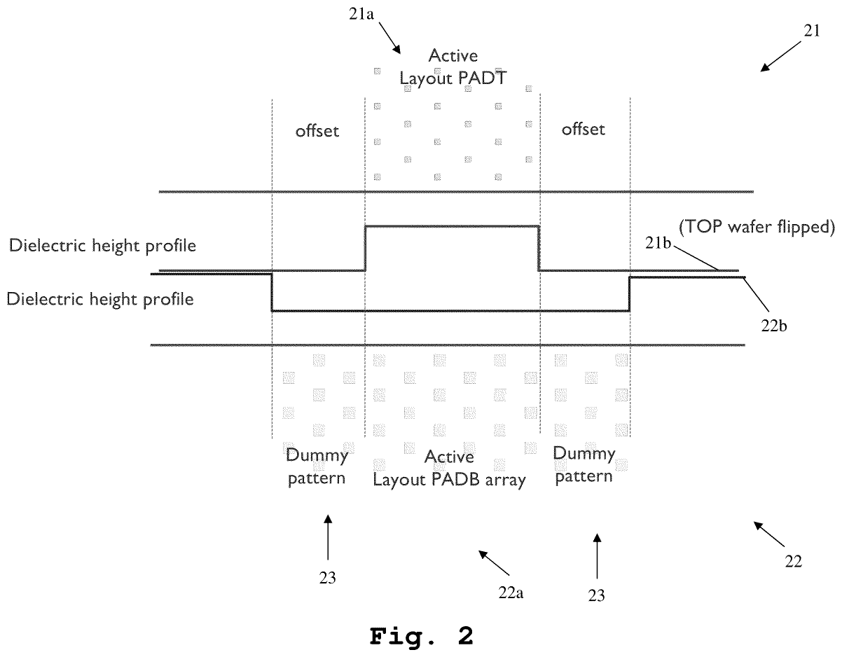

FIG. 2 shows a first exemplary embodiment of an inventive semiconductor product;

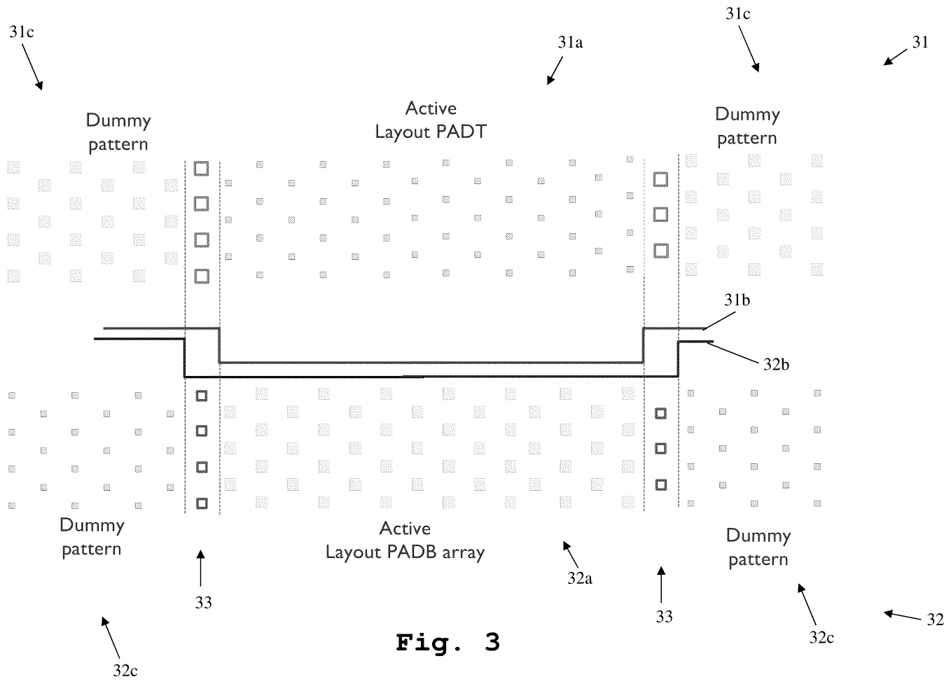

FIG. 3 shows a second exemplary embodiment of an inventive semiconductor product;

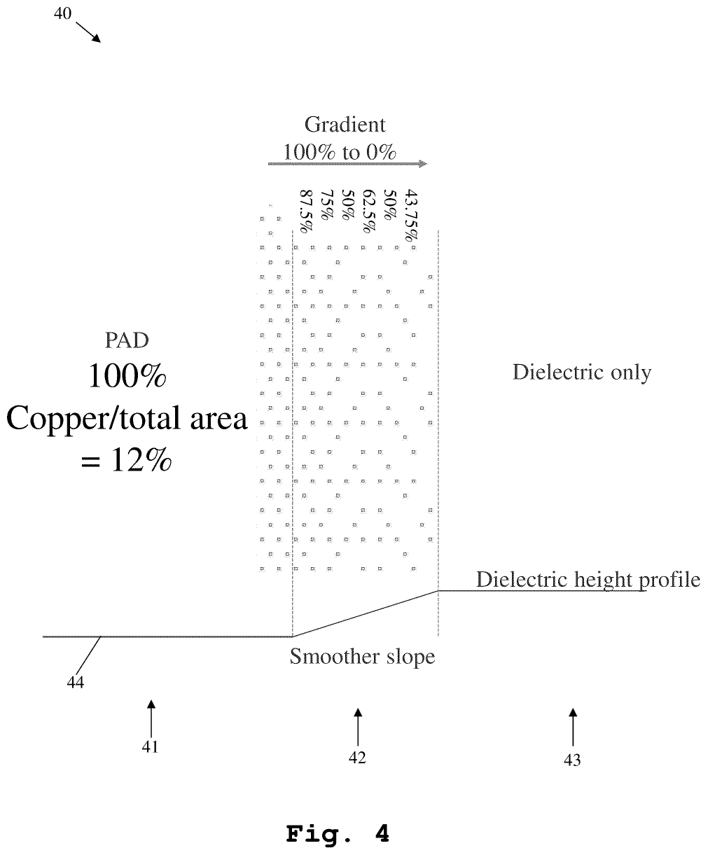

FIG. 4 shows an exemplary embodiment of an inventive transition smoothing based on a gradient profile; and

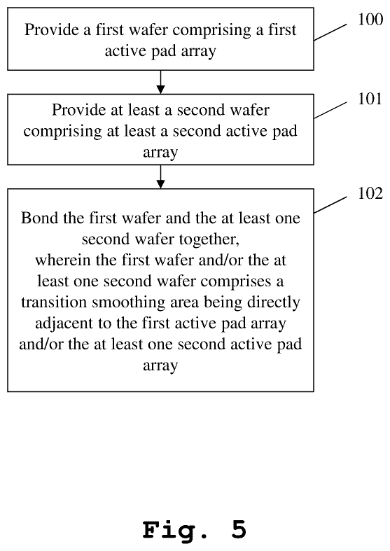

FIG. 5 shows a flow chart of an embodiment of the second aspect of the invention.

Firstly, with special respect to FIG. 1, some introductory explanations should be given in the following. Generally, in the context of bonding techniques, especially hybrid bonding technique, two wafers, exemplarily a top wafer or a first wafer, respectively, and a bottom wafer or a second wafer, respectively, are bonded together.

Typically, the surfaces of the two wafers each have a number of copper (Cu) structures (pads) surrounded by Oxides (Ox). By bonding the two wafers together the Cu pads on both wafers bond together (making an electrical contact) and the surrounding dielectrics also bond together.

Furthermore, the Cu pads are typically arranged in very large arrays of Cu pads, surrounded by equally large areas of pure dielectric. In a successful hybrid bonding process, all the Cu pad to pad bonds make a good electrical contact and all the dielectric also make a good contact. Parameters that have a very big impact on the quality of the hybrid bonding are typically related to the global and the local planarity of both wafers. Typically, most critical failure mechanism are the creation of small or large voids between both wafers that prevent the Cu—Cu bond and dielectric bond, exemplarily Oxid-Oxid bond, from forming.

With respect to said dielectric or dielectric bond, respectively, it is noted that the dielectric can especially comprise or be silicon nitride and/or silicon carbonitride.

FIG. 1 shows Scanning Acoustic Microscopy (SAM) images taken after top and bottom wafer were bonded and annealed. Left image (reference sign 10a) shows the results obtained when top and bottom wafer both have the pad array, with a low to high copper to dielectric percentage transition lying on top of each other. The white square area seen on the SAM image are indicating voids, which are present at the bonding interface. A yield of about 60% is reached using the conventional design.

Moreover, centre (reference sign 10b) and right (reference sign 10c) images correspond to top and bottom wafer being bond to wafer with dielectric layers that do not have any copper pad patterning. The results of these experiments show that the interaction between the pads region lead to voids.

The hybrid bonding technique consists of bonding dielectric and dielectric/copper array region from two wafers, the copper/dielectric region being organized into an array. The area where copper/dielectric element array is present, called pad array, could not yield to 100% successful bonding in the area where pads are present.

Large voids, air gap at the interface between the two bonded wafer, prevented the process to continue further. According to said FIG. 1, a white area in the surface acoustic waves images reveals the voids area obtained for large array, while bonding array on top of each other or on blanket wafers.

Typically, bonding wafers where pad transition occur at the same location results in a higher chance of unsuccessful bonding. Furthermore, similar bonding of these individuals wafers to a blanket carrier resulted in successful bonding.

It is further noted that the Cu pad arrays may especially be made through a single damascene process. The planarity of the surface may then be largely determined by a final chemical mechanical polishing (CMP) process. In this context, it should be made sure that the transition from the arrays with the Cu pads to the large dielectric fields, exemplarily oxide fields, or from arrays with different Cu pads density, is planar, for instance, one area is not recessed relative to the other.

Typically, a step in height, also called roll-off or slope in the following, often appears at the pad/dielectric array to dielectric transition (or low density to high density Cu pads transition). This step/slope is induced by a couple of factors. Vias are etched to connect top layer to underneath layers. Typically, said vias, which have different size and depth, are filled with a barrier layer, copper seed and copper electroplated.

The introduction of a pattern likely introduce a slight change in copper thickness homogeneity between the array area which have a low filling factor with smallest pad size (or no patterned array) compared to the area with a higher filling factor with bigger pad size. When the copper/barrier are mechanically/chemically polished away, the slight difference introduce by the patterns variation especially induce the copper/barrier to be removed first in the region where the highest filling factor is present.

The transition is especially produced due to lower dielectric to barrier selectivity. Once the barrier is completely removed, the dielectric is being CMP'd away slightly faster than the barrier.

These factors especially introduce a step in height with a certain slope at the interface between this patterned/non-patterned area (high/low transition area). The steeper the slope, the lower the chance of successful bonding. Furthermore, the cumulative step in height or slope, which is created at the array to dielectric transition (or low to high density transition), is especially responsible for the void and reduce process yield.

Because the slope from both top and bottom wafer usually land on top of each other, the cumulative effect leads the complete array to void. The cumulative effect is especially responsible for lower yield, a less robust process. Accordingly, it is particularly important to enable successful, robust process integration for bonding, especially hybrid bonding.

In addition to this, it is noted that whereas perfect flatness cannot be achieved, the cumulative effect to a step on both the bottom and the top wafer should be avoided. Furthermore, although the active arrays typically coincide, it should be made sure that the edges of the arrays do not coincide exemplarily by introducing dummy pads around the arrays on one of the wafers of the respective pair.

Now, with respect to FIG. 2, an exemplary embodiment of an inventive semiconductor is product illustrated and described. Said semiconductor product comprises a first wafer 21 comprising a first active pad array 21a, and a second wafer 22 comprising a second active pad array 22a, wherein the first wafer 21 and the second wafer 22 are bonded together especially according to a hybrid bonding technique.

In this context, the first wafer 21 can also be seen as a top wafer, whereas the second wafer 22 can also be seen as a bottom wafer. In addition to this, bottom wafer 22 comprises a transition area 23 being directly adjacent to the second active pad array 22a. As it can further be seen from FIG. 2, said transition area 23 comprises an inactive pad array, exemplarily a dummy pattern or dummy pad array.

Furthermore, the first active pad array 21a comprises a first ratio of an electrically conducting material over the corresponding area of the first active pad array, whereas the second active pad array 22a comprises a second ratio of an electrically conducting material over the corresponding area of the at least one second active pad array.

Exemplarily, it is noted that the electrically conducting material is copper. Further exemplarily, the first ratio of the electrically conducting material is 3%, whereas the second ratio of the electrically conducting material is 12% Moreover, the transition area comprises a third ratio of an electrically conducting material, exemplarily being copper, over the corresponding area of the transition area. Exemplarily, said third ratio is 12%.

For the sake of completeness, it is noted that FIG. 2 additionally illustrates the dielectric height profile 21b regarding the substrate of the first wafer 21, and the dielectric height profile 22b regarding the substrate of the second wafer 22.

Furthermore, the embodiment according to FIG. 2 can be summarized in other words and additionally be complemented as follows:

On one of the two wafers (for instance, the bottom wafer), a dummy pattern of pads is introduced to offset the low to high transition area further away from the low to high transition area that occur on the other paired wafer (for instance, the top wafer).

The steep transition that occurs at the array to dielectric or high to low transition, is now moved away from each other by some distance, enable successful hybrid bonding. The local slope on one wafer is now seeing a flat local surface on the other wafer, the cumulative slope effect no longer plays a detrimental role in the bonding mechanism.

Note that the step in height showed in FIG. 2 may be very local and very small (few nm). The flatness of the surface on which it bonds may have a roughness below 1 nm over a few micron. The long range bonding surface may be considered flat outside of these slope events.

Before FIG. 3 is explained in greater detail in the following, the definition of the filling factor should be mentioned: Ratio of electrically conducting material, exemplarily copper, in an area defined by the repeating unit cell, and/or ratio of copper area over a defined area.

In this context, an area which contains the highest area of copper is defined as the area with a high filling factor, whereas an area with lowest area of copper is defined as the area with a low filling factor. A gradual change of copper surface area (for instance, reducing or increase pad size and/or removing/adding pads) over a defined distance would lead to a smooth change of filling factor, which we call gradient.

In advance, with respect to said gradient, it is noted that a corresponding exemplary embodiment will be explained below in the context of FIG. 4. Now, with respect to FIG. 3, a second exemplary embodiment of the inventive semiconductor product is shown.

Said semiconductor product comprises a first wafer 31 comprising a first active pad array 31a, and a second wafer 32 comprising at least a second active pad array 32a. In this context, the first wafer 31 and the second wafer 32 are bonded together especially according to a hybrid bonding technique.

In addition to this, each of the first wafer 31, exemplarily the top wafer, and the second wafer 32, exemplarily the bottom wafer, comprises a transition area 33 being directly adjacent to the first active pad array 31a or the second active pad array 32a, respectively. Furthermore, the transition area 33 comprises an inactive pad array as it can also be seen from FIG. 3.

Moreover, the first active pad array 31a comprises a first ratio of an electrically conducting material, exemplarily copper, over the corresponding area of the first active pad array 31a, whereas the second active pad array 32a comprises a second ratio of an electrically conducting material, exemplarily copper, over the corresponding area of the second active pad array 32a.

In this context, the first ratio of the electrically conducting material is 3%, whereas the second ratio of the electrically conducting material is 12%. Furthermore, the transition area 33 comprises a third ratio of an electrically conducting material, exemplarily being copper, over the corresponding area of the transition area 33. For instance, said third ratio is 12%.

As it can further be seen from FIG. 3, the first wafer 31 comprises a first further area 31c comprising a first further ratio of an electrically conducting material, exemplarily copper, over the corresponding area of the first further area 31c, whereas the second wafer 32 comprises a second further area 32c comprising a second further ratio of an electrically conducting material, exemplarily copper, over the corresponding area of the second further area 32c. Exemplarily, the first further ratio is 12%, whereas the second further ratio is 3%.

It is further noted that the first further area 31c is directly adjacent to the transition area 33 and not directly adjacent to the first active pad array 31a, whereas the second further area 32c is directly adjacent to the transition area 33 and not directly adjacent to the second active pad array 32a. Moreover, the first further area 31c comprises a first further inactive pad array, exemplarily a dummy pattern or dummy pad array, whereas the second further area 32c comprises a second further inactive pad array, exemplarily a dummy pattern or dummy pad array.

For the sake of completeness, it is noted that FIG. 3 additionally illustrates the dielectric height profile 31b regarding the substrate of the first wafer 31, and the dielectric height profile 32b regarding the substrate of the second wafer 32.

Furthermore, the embodiment according to FIG. 3 can be summarized in other words and additionally be complemented as follows:

The layout design can be varied to reverse the profile especially in order to modify the slope orientation. On one wafer the arrays with pads is sticking out, whereas on the other wafer the arrays with pads are recessed (see FIG. 3).

A change of filling factor percentage can help to engineer the slope direction and enable wafer surface to follow each other rather than separating wafer from each other. When wafer pairs are being bonded, the transition slopes are now slotting within each other.

This engineering brings the arrays closer to each other, facilitating the bonding and resulting in a higher chance of successful bonding, especially hybrid bonding. The cumulative effect which is especially responsible for voids can advantageously be cancelled. A small offset, especially in the form of the transition area 33, may be required to take into account potential misalignment.

Now, with respect to FIG. 4, illustrating an exemplary embodiment of an inventive transition smoothing based on a gradient profile, it is noted that a gradient change of filling factor can also be introduced to reduce step in height, slope sharpness.

This can be introduced by changing the pattern pitch, the pattern arrangement or change the size of the pad (bigger or smaller critical dimension, CD), depending on what is being looked after. Note the change of CD will introduce process change which may have an impact on the overall integration. This solution might be particularly interesting when the filling factor is very high in the array and that regions on the rest of the wafer are dielectric.

A smooth, controlled transition will especially be required to enable successful bonding to occur everywhere on the wafer, not just in the array. Advantageously, a filling factor change could be achieved in the following ways: Change of pattern arrangement and/or change of element shape such as bigger CD, rectangular shape, cross-like shape, round shape, diamond shape. Further advantageously, it is noted that all shapes could potentially be used for reducing/increasing the filling factor. As a further advantage, said shape or shapes, respectively, or another shape in this context can especially be based on at least one of a lines type structure, a zig-zag type structure, a meanders type structure, or any combination thereof.

Exemplarily, in FIG. 4 a part of a wafer 40 is shown, wherein the corresponding dielectric height profile 44 is also depicted. In this context, a first area 41 comprises an active pad array with for example 12% filling factor or ratio of copper over the corresponding area of said active pad array, respectively.

In addition to this, a second area 42 is directly adjacent to said first area 41 and to a third area 43, wherein said third area 43 comprises only dielectric material and is not directly adjacent to the first area 41. As it can be seen regarding the second area 42, the corresponding ratio of copper over the second area 42 changes according to a gradient.

Exemplarily, the corresponding gradient profile of the second area 42 is 87.5%-75%-50%-62.5%-(62.5%)-50%-43.75% especially with respect to the filling factor of the area 41 corresponding to 100%. Accordingly, in this exemplary case, the filling factor profile of the second area 42 is as follows: 10.5%-9%-6%-7.5%-(7.5%)-6%-5.25%.

Finally, FIG. 5 shows a flow chart of an embodiment of the inventive method for manufacturing a semiconductor product. In a first step 100, a first wafer comprising a first active pad array is provided. Then, in a second step 101, at least a second wafer comprising at least a second active pad array is provided. Furthermore, in a third step 102, the first wafer and the at least one second wafer are bonded together. In this context, the first wafer and/or the at least one second wafer comprises a transition area being directly adjacent to the first active pad array and/or the at least one second active pad array.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with to only respect one of several implementations, such feature may be combined with one or more other features of the other implementations as may be desired and advantageous for any given or particular application.

1-15. (canceled)

16. A semiconductor product, comprising:
a first wafer comprising a first active pad array; and
a second wafer comprising a second active pad array;
wherein the first wafer and the second wafer are bonded together;
wherein the first wafer and/or the second wafer comprise a transition area directly adjacent to the first active pad array and/or the second active pad array, the transition area comprising an inactive pad array; and
wherein the first active pad array comprises a first ratio of an electrically conducting material over the corresponding area of the first active pad array, the first ratio ranging from about 2% to about 4%.

17. The semiconductor product of claim 16, wherein the first wafer and the second wafer are bonded together using a hybrid bonding technique.

18. The semiconductor product of claim 16, wherein the second active pad array comprises a second ratio of an electrically conducting material over the corresponding area of the second active pad array and/or wherein the electrically conducting material comprises copper, cobalt, tungsten, or combinations thereof.

19. The semiconductor product of claim 18, wherein the second ratio is between about 1% and about 27%.

20. The semiconductor product of claim 19, wherein the second ratio is between about 1% and about 19%.

21. The semiconductor product of claim 20, wherein the second ratio is between about 11% and about 13%.

22. The semiconductor product of claim 16, wherein the transition area comprises a third ratio of an electrically conducting material comprising copper, cobalt, tungsten, or combinations thereof over the corresponding area of the transition area.

23. The semiconductor product of claim 22, wherein the third ratio does not deviate more than about 400% from the second ratio of the electrically conducting material over the corresponding area of the second active pad array and/or does not deviate more than about 400% from the first ratio of the electrically conducting material over the corresponding area of the first active pad array.

24. The semiconductor product of claim 22, wherein the third ratio does not deviate more than about 225% from the second ratio of the electrically conducting material over the corresponding area of the second active pad array and/or does not deviate more than about 225% from the first ratio of the electrically conducting material over the corresponding area of the first active pad array.

25. The semiconductor product of claim 22, wherein the third ratio does not deviate more than about 56.25% from the second ratio of the electrically conducting material over the corresponding area of the second active pad array and/or does not deviate more than about 56.25% from the first ratio of the electrically conducting material over the corresponding area of the first active pad array.

26. The semiconductor product of claim 16, wherein the first wafer contains a first further area comprising a first further ratio of an electrically conducting material over the corresponding area of the first further area and wherein the first further area is directly adjacent to the transition area and/or not directly adjacent to the first active pad array.

27. The semiconductor product of claim 24, wherein the second wafer comprises a second further area comprising a second further ratio of an electrically conducting material over the corresponding area of the second further area, wherein the second further area is directly adjacent to the transition area and/or not directly adjacent to the second active pad array and wherein the electrically conducting material comprises copper, cobalt, tungsten, or combinations thereof.

28. The semiconductor product according to claim 27, wherein the first further area comprises a first further inactive pad array and/or wherein the second further area comprises a second further inactive pad array.

29. The semiconductor product of claim 28, wherein the first further ratio of the electrically conducting material does not deviate more than about 56.25% from the second ratio of the electrically conducting material over the corresponding area of the second active pad array and/or the second further ratio of the electrically conducting material does not deviate more than about 56.25% from the first ratio of the electrically conducting material over the corresponding area of the first active pad array.

30. The semiconductor product of claim 28, wherein the first further ratio of the electrically conducting material does not deviate more than about 25% from the second ratio of the electrically conducting material over the corresponding area of the second active pad array and/or the second further ratio of the electrically conducting material does not deviate more than about 25% from the first ratio of the electrically conducting material over the corresponding area of the first active pad array.

31. The semiconductor product of claim 28, wherein the first further ratio of the electrically conducting material does not deviate more than about 12.5% from the second ratio of the electrically conducting material over the corresponding area of the second active pad array and/or the second further ratio of the electrically conducting material does not deviate more than about 12.5% from the first ratio of the electrically conducting material over the corresponding area of the first active pad array.

32. The semiconductor product of claim 28, wherein the first further ratio of the electrically conducting material over the corresponding area of the first further area changes according to a first gradient and/or the second further ratio of the electrically conducting material over the corresponding area of the second further area changes according to a second gradient.

33. The semiconductor product of claim 22, wherein the third ratio of the electrically conducting material over the corresponding area of the transition area changes according to a third gradient.

34. A method for manufacturing a semiconductor product, comprising:
providing a first wafer containing a first active pad array;
providing a second wafer comprising a second active pad array; and
bonding the first wafer and the second wafer together;
wherein the first wafer and/or the second wafer comprises a transition area directly adjacent to the first active pad array and/or the second active pad array;
wherein the transition area comprises an inactive pad array; and
wherein the first active pad array comprises a first ratio of an electrically conducting material over the corresponding area of the first active pad array and wherein the first ratio of the electrically conducting material is between about 2% and about 4%.

35. The method of claim 34, wherein the second active pad array comprises a second ratio of an electrically conducting material over the corresponding area of the second active pad array, the first ratio being different from the second ratio.
